(19) United States
(12) Patent Application Publication
(10) Pub. No.: US 2020/0083175 A1
(43) Pub. Date: Mar. 12, 2020

(54) SEMICONDUCTOR DEVICE AND MANUFACTURING METHOD THEREOF

(71) Applicant: TOSHIBA MEMORY CORPORATION, Minato-ku (JP)

(72) Inventor: Satoshi HONGO, Yokkaichi (JP)

(73) Assignee: TOSHIBA MEMORY CORPORATION, Minato-ku (JP)

(21) Appl. No.: 16/253,540

(22) Filed: Jan. 22, 2019

(30) Foreign Application Priority Data
Sep. 12, 2018 (JP) 2018-170689

(51) Int. Cl. H01L 23/532; H01L 23/00; H01L 23/522; H01L 21/768; H01L 21/321

(52) U.S. Cl. CPC H01L 23/53295; H01L 24/80; H01L 23/53266; H01L 23/5226; H01L 2224/80896; H01L 21/76832; H01L 21/76877; H01L 21/3212; H01L 2224/80895; H01L 21/76897

(57) ABSTRACT

A device includes a first semiconductor substrate and a second semiconductor substrate. A first insulating film is provided on a first face of the first semiconductor substrate. A first metal layer covers an inner surface of a first grove provided on the first insulating film. A first electrode is provided on the first metal layer and embedded in the first groove. The second semiconductor substrate has a second face facing the first face of the first semiconductor substrate. A second insulating film is provided on the second face of the second semiconductor substrate and is attached to the first insulating film. A second electrode is embedded in a second groove provided on the second insulating film and is connected to the first electrode. An end part of the first metal layer is recessed toward the first semiconductor substrate relative to a surface of the first insulating film.

### CROSS REFERENCE TO RELATED APPLICATIONS

This application is based upon and claims the benefit of priority from the prior Japanese Patent Application No. 2018-170689, filed on Sep. 12, 2018, the entire contents of which are incorporated herein by reference.

### FIELD

The embodiments of the present invention relate to a semiconductor device and manufacturing method thereof.

### BACKGROUND

A technique of attaching a plurality of semiconductor substrates to each other to connect electrodes or the like respectively formed on the semiconductor substrates to each other has been developed. However, when material layers on the semiconductor substrates are flattened, a part thereof may be protruded. In this case, there is a risk that a gap is formed at the interface between the semiconductor substrates when the semiconductor substrates are attached to each other, which leads to poor connection between the electrodes or poor attachment between the semiconductor substrates.

### BRIEF DESCRIPTION OF THE DRAWINGS

FIG. 1 is a sectional view illustrating an example of a wiring part of a semiconductor device according to the present embodiment;

FIG. 2 is a sectional view illustrating an example of a configuration of a broken line frame in FIG. 1;

FIGS. 3A to 6B are sectional views illustrating an example of the manufacturing method of the first device;

FIG. 7A is an enlarged sectional view of a broken line frame illustrated in FIG. 6A;

FIG. 7B is an enlarged sectional view of a broken line frame illustrated in FIG. 6B;

FIGS. 8A to 9C showing a process of attaching the first substrate and the second substrate to each other; and

FIG. 10 is a sectional view illustrating a manner that the insulating films are misaligned on the attachment face.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a semiconductor substrate on which semiconductor elements are provided is assumed as “an upper direction”. Therefore, the term “upper direction” or “lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor device according to the present embodiment includes a first semiconductor substrate and a second semiconductor substrate. A first insulating film is provided on a first face of the first semiconductor substrate. A first metal layer covers an inner surface of a first grove provided on the first insulating film. A first electrode part is provided on the first metal layer and embedded in the first groove. The second semiconductor substrate has a second face facing the first face of the first semiconductor substrate. A second insulating film is provided on the second face of the second semiconductor substrate and is attached to the first insulating film. A second electrode part is embedded in a second groove provided on the second insulating film and is connected to the first electrode part. An end part of the first metal layer is recessed toward the first semiconductor substrate relative to a surface of the first insulating film.

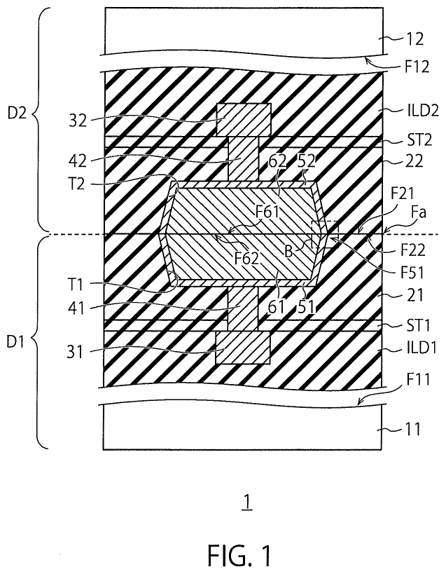

FIG. 1 is a sectional view illustrating an example of a wiring part of a semiconductor device according to the present embodiment. A semiconductor device 1 includes a first device D1 provided on a substrate 11 and a second device D2 provided on a substrate 12. Although not particularly limited thereto, the first and second devices D1 and D2 can be, for example, a semiconductor memory and a controller therefor, respectively.

### (Configuration of First Device D1)

The first device D1 includes the substrate 11, an insulating film 21, a wire 31, a contact plug 41, a barrier metal 51, and an electrode part 61.

The substrate 11 being a first semiconductor substrate is, for example, a silicon substrate and has semiconductor elements (not illustrated) placed on a surface (first face) F11 thereof. The semiconductor elements are, for example, a transistor, a memory cell array, a resistive element, and a capacitor.

The insulating film 21 being a first insulating film is provided above the surface F11 of the substrate 11 to cover the semiconductor elements. For example, an insulating film such as silicon dioxide film is used as the insulating film 21. A stopper film ST1 is provided between the insulating film 21 and the wire 31. The stopper film ST1 functions as an etching stopper during formation of the contact plug 41. For example, a silicon nitride film is used as the stopper film ST1.

The wire 31 is provided in the insulating film 21. The wire 31 is electrically connected to the semiconductor elements placed on the substrate 11 via contacts or other wires. The contact plug 41 is also provided in the insulating film 21. The contact plug 41 is provided between the wire 31 and the barrier metal 51 or the electrode part 61 and electrically connects these members. For example, a low-resistance metal such as copper, aluminum, or tungsten is used as the wire 31 and the contact plug 41.

The barrier metal 51 and the electrode part 61 are embedded in the insulating film 21. The electrode part 61 being a first electrode part is embedded in a first groove T1 provided on the insulating film 21 and is provided on the barrier metal 51 in the first groove T1. The electrode part 61 has a surface (first electrode face) F61 exposed on the surface F21 of the insulating film 21. The surface F61 is substantially flush with the surface F21 of the insulating film 21. For example, a conductive metal such as copper is used as the electrode part 61.

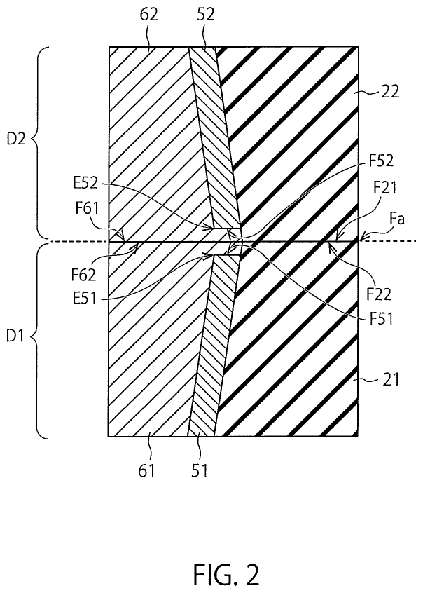

The barrier metal 51 being a first metal layer is provided between the insulating film 21 and the electrode part 61 and suppresses the material of the electrode part 61 from diffusing into the insulating film 21. The barrier metal 51 substantially covers the inner surface of the first groove T1 provided on the insulating film 21 and also substantially covers the side surface and the bottom surface of the electrode part 61 except for the surface F61. A surface F51 of an end part of the barrier metal 51 is recessed toward the substrate 11 relative to the surface F21 of the insulating film 21. For example, a conductive metal such as titanium is used as the barrier metal 51. A configuration of the barrier metal 51 near the end part will be explained later with reference to FIG. 2.

### (Configuration of Second Device D2)

The second device D2 includes the substrate 12, an insulating film 22, a wire 32, a contact plug 42, a barrier metal 52, and an electrode part 62. While the second device D2 has a wiring configuration similar to that of the first device D1, the vertical relation thereof is opposite to that in the first device D1. The second device D2 is attached to the insulating film 21 of the first device D1 at its insulating film 22. An attachment face between the insulating film 21 and the insulating film 22 is denoted by Fa.

The substrate 12 being a second semiconductor substrate is, for example, a silicon substrate and has a surface (second face) F12 facing the surface F11 of the substrate 11. Semiconductor elements (not illustrated) are placed on the surface F12 of the substrate 12.

The insulating film 22 being a second insulating film is provided above the surface F12 of the substrate 12 to cover the semiconductor elements. For example, an insulating film such as a silicon dioxide film is used as the insulating film 22. The insulating film 22 is attached to the insulating film 21 of the first device D1 on the attachment face Fa. A stopper film ST2 is provided between the insulating film 22 and the wire 32. The stopper film ST2 functions as an etching stopper during formation of the contact plug 42. For example, a silicon nitride film is used as the stopper film ST2.

The wire 32 is provided in the insulating film 22. The wire 32 is electrically connected to the semiconductor elements placed on the substrate 12 via contacts or other wires. The contact plug 42 is also provided in the insulating film 22. The contact plug 42 is provided between the wire 32 and the barrier metal 52 or the electrode part 62 and electrically connects these members. For example, a low-resistance metal such as copper, aluminum, or tungsten is used as the wire 32 and the contact plug 42.

The barrier metal 52 and the electrode part 62 are embedded in the insulating film 22. The electrode part 62 being a second electrode part is embedded in a second groove T2 provided on the insulating film 22 and is provided on the barrier metal 52 in the second groove T2. The electrode part 62 has a surface (second electrode face) F62 exposed on the surface F22 of the insulating film 22. The surface F62 is substantially flush with the surface F22 of the insulating film 22. The electrode part 62 is connected to the electrode part 61 of the first device D1 on the attachment face Fa. For example, a conductive metal such as copper is used as the electrode part 62.

The barrier metal 52 being a second metal layer is provided between the insulating film 22 and the electrode part 62 and suppresses the material of the electrode part 62 from diffusing into the insulating film 22. The barrier metal 52 substantially covers the inner surface of the second groove T2 provided on the insulating film 22 and also substantially covers the side surface and the bottom surface of the electrode part 62 except for the surface F62. A surface F52 of an end part of the barrier metal 52 is recessed toward the substrate 12 relative to the surface F22 of the insulating film 22. For example, a conductive metal such as titanium is used as the barrier metal 52. A configuration of the barrier metal 52 near the end part is explained with reference to FIG. 2.

FIG. 2 is a sectional view illustrating an example of a configuration of a broken line frame B in FIG. 1. The insulating film 21 of the first device D1 and the insulating film 22 of the second device D2 are attached to each other on the attachment face Fa. The electrode part 61 and the electrode part 62 are also attached to each other on the attachment face Fa. In this case, the surface F21 of the insulating film 21 and the surface F22 of the insulating film 22 substantially match the attachment face Fa. The surface F61 of the electrode part 61 and the surface F62 of the electrode part 62 also substantially match the attachment face Fa. However, it suffices that the electrode part 61 and the electrode part 62 are connected to each other, and the interface between the surfaces F61 and F62 can be slightly misaligned in the vertical direction from the attachment face Fa.

Meanwhile, the surface F51 of an end part E51 of the barrier metal 51 is recessed toward the substrate 11 relative to the surface F21 of the insulating film 21. Furthermore, the surface F51 is recessed toward the substrate 11 relative to the surface F61 of the electrode part 61. Therefore, the barrier metal 51 is recessed from the surface F21 of the insulating film 21 and the surface F61 of the electrode part 61 (that is, the attachment face Fa). The material (copper, for example) of the electrode part 61 or 62 enters into a recess (between the surface F51 and the attachment face Fa) of the barrier metal 51.

The surface F52 of an end part E52 of the barrier metal 52 is recessed toward the substrate 12 relative to the surface F22 of the insulating film 22. Furthermore, the surface F52 of the end part E52 of the barrier metal 52 is recessed toward the substrate 12 relative to the surface F62 of the electrode part 62. Therefore, the barrier metal 52 is recessed from the surface F22 of the insulating film 22 and the surface F62 of the electrode part 62 (that is, the attachment face Fa). The material (copper, for example) of the electrode part 61 or 62 enters into a recess (between the surface F52 and the attachment face Fa) of the barrier metal 52. In this way, the material of the electrode part 61 or 62 is provided in a gap between the end part E51 of the barrier metal 51 and the end part E52 of the barrier metal 52.

As will be described later, there is a gap between the end part E51 of the barrier metal 51 and the end part E52 of the barrier metal 52 immediately after attachment of the substrates 11 and 12. The material (copper, for example) of the electrode part 61 or 62 expands due to a subsequent thermal treatment and the material of the electrode part 61 or 62 enters between the end part E51 of the barrier metal 51 and the end part E52 of the barrier metal 52. Therefore, the material of the electrode part 61 or 62 is consequently provided between the end part E51 of the barrier metal 51 and the end part E52 of the barrier metal 52.

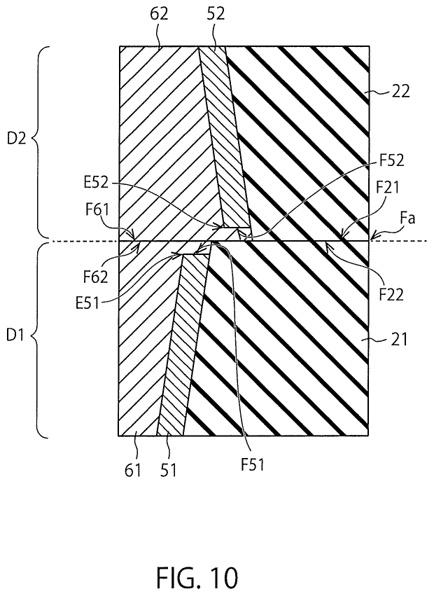

The surface F51 of the end part E51 of the barrier metal 51 and the surface F52 of the end part E52 of the barrier metal 52 do not always face each other, which will be explained later with reference to FIG. 10. In a case where the positions of the barrier metals 51 and 52 are misaligned in the attachment face Fa, the end part E51 of the barrier metal 51 sometimes faces the insulating film 22 or the electrode part 62. The end part E52 of the barrier metal 52 sometimes faces the insulating film 21 or the electrode part 61. In this case, the material (copper, for example) of the electrode part 61 or 62 enters between the end part E51 of the barrier metal 51 and the insulating film 22 or the electrode part 62. The material (copper, for example) of the electrode part 61 or 62 enters between the end part E52 of the barrier metal 52 and the insulating film 21 or the electrode part 61.

Due to the end part E51 of the barrier metal 51 being thus recessed toward the substrate 11 relative to the surface F21 of the insulating film 21, the barrier metal 51 does not contact the insulating film 22, the barrier metal 52, or the electrode part 62 and does not hinder attachment between the insulating film 21 and the insulating film 22 when the substrates 11 and 12 are attached to each other. Similarly, due to the end part E52 of the barrier metal 52 being recessed toward the substrate 12 relative to the surface F22 of the insulating film 22, the barrier metal 52 does not contact the insulating film 21, the barrier metal 51, or the electrode part 61 and does not hinder attachment between the insulating film 21 and the insulating film 22 when the substrates 11 and 12 are attached to each other. Accordingly, poor connection between the electrode parts 61 and 62 or poor attachment between the substrates 11 and 12 can be suppressed.

Meanwhile, the recessed ends E51 and E52 of the barrier metals 51 and 52 form a gap between the surfaces F21 and F22 of the insulating films 21 and 22. However, the material of the electrode part 61 or 62 enters into this gap in the thermal treatment. Therefore, the gap between the surfaces F21 and F22 is consequently filled with the material of the electrode part 61 or 62. Even if there is a gap between the electrode part 61 and the electrode part 62, the material of the electrode part 61 or 62 expands and fills the gap in the thermal treatment.

While both the barrier metals 51 and 52 can be recessed as illustrated in FIG. 2, only either one of the barrier metals 51 and 52 can be recessed. This is because the gap between the first device D1 and the second device D2 can be controlled to some extent even with only one of the barrier metals 51 and 52 being recessed.

A manufacturing method of the first and second devices D1 and D2 is explained next.

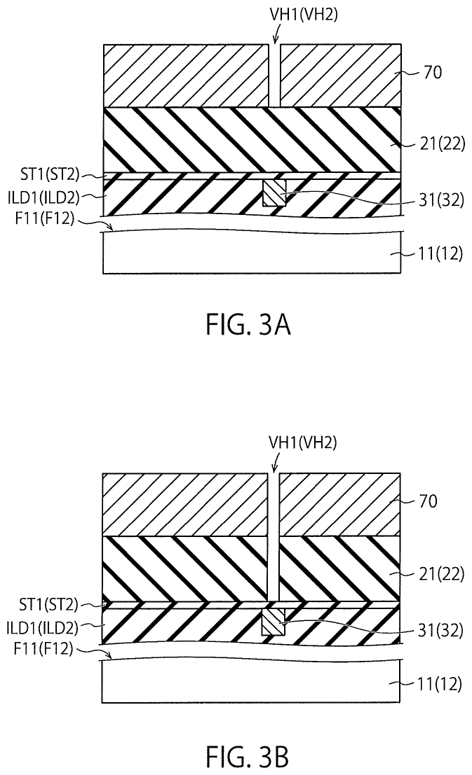

FIGS. 3A to 6B are sectional views illustrating an example of the manufacturing method of the first device D1. While being somewhat different from the first device D1 in the planar layout, the second device D2 can basically be formed by an identical manufacturing method to that of the first device D1. Therefore, the manufacturing method of the first device D1 is explained and explanations of the manufacturing method of the second device D2 are appropriately omitted. Reference numerals in parentheses in FIGS. 3A to 7B correspond to the constituent elements of the second device D2.

First, semiconductor elements (not illustrated) such as a transistor are formed on the surface (first face) F11 of the substrate 11. Next, an interlayer dielectric film ILD1 that covers the semiconductor elements is formed above the surface F11 of the substrate 11 and the wire 31 is formed in the interlayer dielectric film ILD1 as illustrated in FIG. 3A. Further, the stopper film ST1 and the insulating film (first insulating film) 21 are formed on the interlayer dielectric film ILD1 and the wire 31. The stopper film ST1 is, for example, a silicon nitride film and the insulating film 21 is, for example, a silicon dioxide film.

Subsequently, a mask material 70 is deposited on the insulating film 21, and the mask material 70 is processed using a lithography technique and an etching technique to form a pattern of a via hole VH1. For example, an insulating film such as a silicon dioxide film is used as the mask material 70.

Next, the insulating film 21 is processed by an RIE (Reactive Ion Etching) method using the mask material 70 as a mask as illustrated in FIG. 3B. Accordingly, the via hole VH1 is formed in the insulating film 21. At that time, the stopper film ST1 functions as an etching stopper and the via hole VH1 is formed to reach the surface of the stopper film ST1.

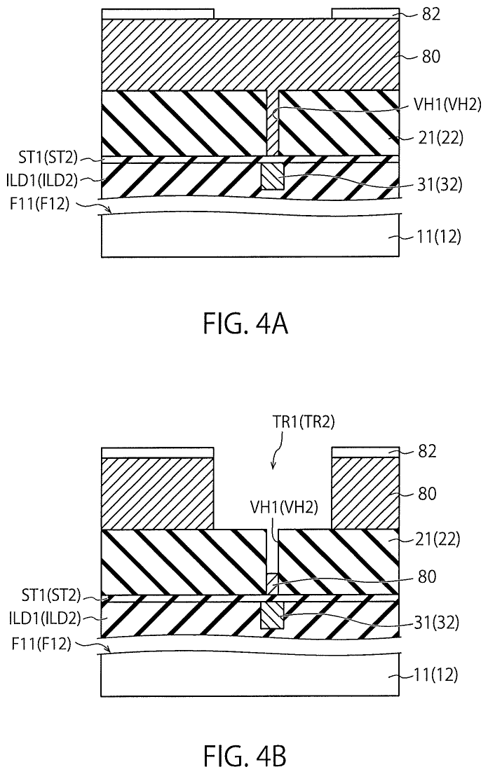

After the mask material 70 is removed, a mask material 80 is deposited in the via hole VH1 and on the insulating film 21 as illustrated in FIG. 4A. For example, an insulating film such as a silicon dioxide film is used as the mask material 80. Next, a resist 82 is formed on the mask material 80 using a lithography technique and the resist 82 in a region where the electrode part 61 is to be formed is removed.

Subsequently, the mask material 80 is etched using the resist 82 as a mask as illustrated in FIG. 4B. Accordingly, the mask material 80 in the formation region for the electrode part 61 is removed. A part of the mask material 80 in the via hole VH1 remains.

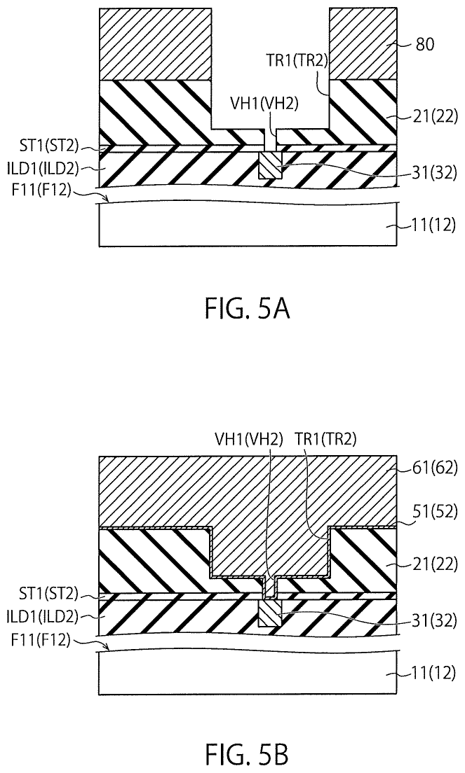

Next, the insulating film 21 is etched by the RIE method using the mask material 80 as a mask as illustrated in FIG. 5A. Accordingly, the insulating film 21 in the formation region for the electrode part 61 is removed and a trench TR1 being a first groove is formed. At that time, a part of the insulating film 21 in the formation region for the electrode part 61 is left and the via hole VH1 remains at a lower part of the insulating film 21. The mask material 80 in the via hole VH1 is removed by this etching.

Subsequently, the stopper film ST1 provided on the bottom of the via hole VH1 is etched to expose the wire 31 on the bottom of the via hole VH1 as illustrated in FIG. 5A.

After the mask material 80 is removed, the inner surface of the via hole VH1 and the inner surface of the trench TR1 are covered with the barrier metal 51 being the first metal layer. Further, the material of the electrode part 61 is deposited on the barrier metal 51 to fill the trench TR1 with the material of the electrode part 61 being the first electrode part. For example, titanium is used as the barrier metal 51. Copper is used, for example, as the material of the electrode part 61.

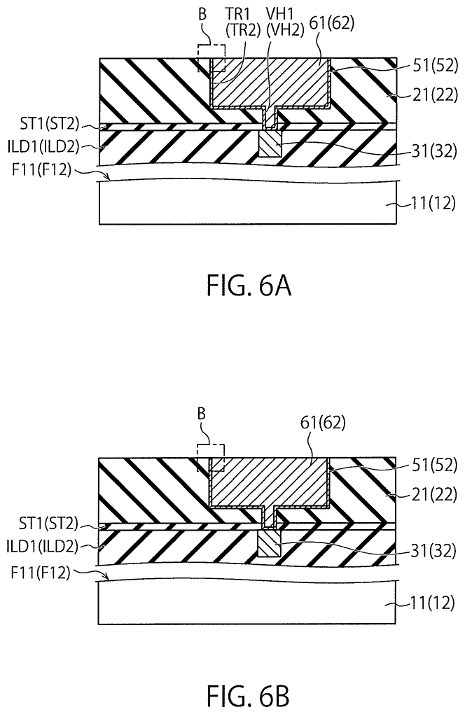

Next, the materials of the electrode part 61 and the barrier metal 51 are polished using a CMP (Chemical Mechanical Polishing) method until the insulating film 21 is exposed as illustrated in FIG. 6A. Accordingly, the electrode part 61 and the barrier metal 51 embedded in the trench TR1 and the via hole VH1 are formed.

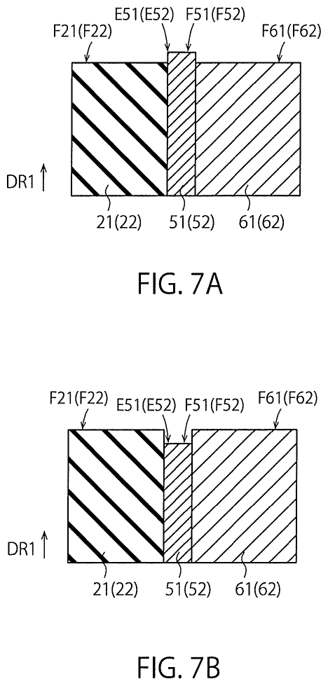

Even after flattening by the CMP method, the barrier metal 51 sometimes protrudes slightly from the insulating film 21 or the electrode part 61. For example, FIG. 7A is an enlarged sectional view of a broken line frame B illustrated in FIG. 6A. FIG. 7A illustrates the end part E51 of the barrier metal 51 and a peripheral part thereof immediately after being flattened by the CMP method. While the insulating film 21 and the electrode part 61 are flattened to substantially same heights, the surface F51 of the end part E51 of the barrier metal 51 protrudes from the surface F21 of the insulating film 21 and the surface F61 of the electrode part 61 in a direction DR1 away from the substrate 11. For example, the height (the height of a protrusion) of the surface F51 of the barrier metal 51 relative to the surface F21 of the insulating film 21 is about 8 nanometers. If the end part E51 of the barrier metal 51 protrudes in this way, a gap is formed between the insulating film 21 and the insulating film 22 as described above when the substrate 11 and the substrate 12 are attached to each other.

In order to solve this problem, in the present embodiment, the barrier metal 51 is selectively etched to recess the end part E51 toward the substrate 11 relative to the surface F61 of the electrode part 61 and/or the surface F21 of the insulating film 21 after the barrier metal 51 and the electrode part 61 are polished as illustrated in FIG. 6B. For example, FIG. 7B is an enlarged sectional view of a broken line frame B illustrated in FIG. 6B. FIG. 7B illustrates the end part E51 of the barrier metal 51 and a peripheral part thereof after being flattening by the CMP method is performed and the barrier metal 51 is etched. The surface F51 of the end part E51 of the barrier metal 51 is recessed in a direction of the substrate 11 (an opposite direction to the direction DR1) relative to the surface F21 of the insulating film 21 and/or the surface F61 of the electrode part 61 by the etching of the barrier metal 51. Due to thus recessing of the end part E51 of the barrier metal 51, it is possible to suppress a gap from being formed between the insulating film 21 and the insulating film 22 when the substrate 11 and the substrate 12 are attached to each other. This suppresses poor connection between the electrode parts 61 and 62 or poor attachment between the insulating films 21 and 22.

When titanium is used, for example, as the barrier metal 51 and copper is used, for example, as the electrode part 61, a wet etching method using a hydrogen peroxide solution is used for the etching of the barrier metal 51. This enables the barrier metal 51 to be selectively etched and recessed.

The first device D1 is formed in this way. As indicated by the reference numerals in the parentheses in FIGS. 3A to 7B, the second device D2 can be formed in an identical manner to the first device D1.

For example, semiconductor elements (not illustrated) are formed on the surface (second face) F12 of the substrate 12, and an interlayer dielectric film ILD2, the wire 32, the stopper film ST2, and the insulating film (second insulating film) 22 are formed above the surface F12 of the substrate 12 (FIG. 3A).

Next, after a via hole VH2 is formed in the insulating film 22 using the stopper film ST2 as an etching stopper, the insulating film 22 is removed in a region where the electrode part 62 is to be formed, and a trench TR2 being a second groove is formed (FIGS. 3B to 5A).

Subsequently, after the stopper film ST2 is removed to expose the wire 32, the materials of the barrier metal 52 and the electrode part 62 are deposited to fill the trench TR2 with the material of the electrode part 62 being the second electrode part (FIG. 5B).

Next, the materials of the electrode part 62 and the barrier metal 52 are polished until the insulating film 22 is exposed (FIG. 6A). At that time, the surface F52 of the end part E52 is protruded in a direction away from the substrate 12 relative to the surface F22 of the insulating film 22 and the surface F62 of the electrode part 62.

Subsequently, the barrier metal 52 is selectively etched to recess the end part E52 toward the substrate 12 relative to the surface F62 of the electrode part 62 and/or the surface F22 of the insulating film 22 (FIGS. 6B to 7B). The second device D2 is formed in this way.

Next, the substrate 11 and the substrate 12 are attached to each other in such a manner that the surface F11 and the surface F12 face each other.

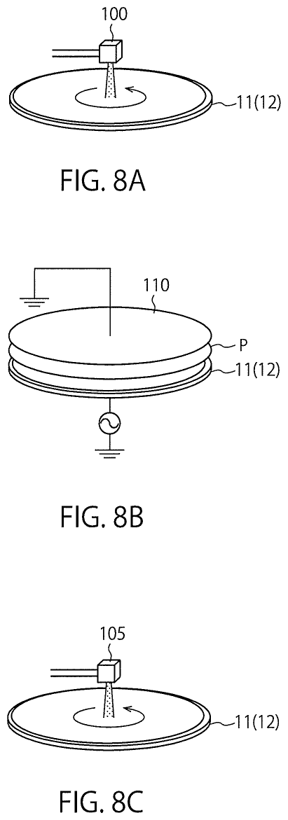

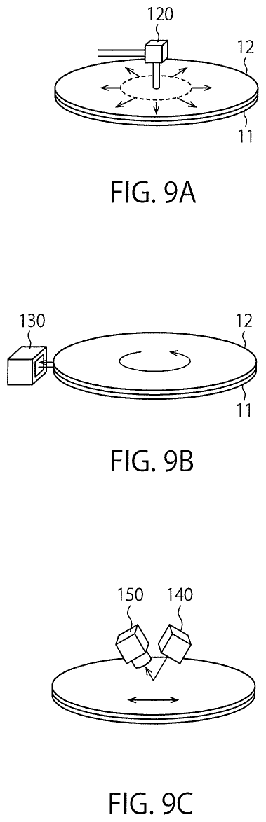

A process of attaching the substrate 11 and the substrate 12 to each other is explained with reference to FIGS. 8A to 9C. Reference numerals in parentheses in FIGS. 8A to 8C correspond to the constituent elements of the substrate 12.

First, as illustrated in FIG. 8A, ozone water is supplied from a nozzle 100 onto the surface F11 of the substrate 11. Accordingly, the surfaces F21, F51, and F61 of the insulating film 21, the barrier metal 51, and the electrode part 61 on the surface F11 of the substrate 11 are cleaned with the ozone water.

Next, the surface F21 of the insulating film 21 is activated by N₂ plasma P using a plasma generating device 110 as illustrated in FIG. 8B. Accordingly, for example, dangling bonds of a silicon dioxide film are formed on the surface F21 of the insulating film 21.

Subsequently, a cleaning solution (pure water, for example) and a carrier gas (nitrogen, for example) are supplied from a nozzle 105 to perform two-fluid cleaning of the surface F11 of the substrate 11 as illustrated in FIG. 8C. Accordingly, two-fluid cleaning of the surfaces F21, F51, and F61 of the insulating film 21, the barrier metal 51, and the electrode part 61 on the surface F11 of the substrate 11 is performed. Along therewith, the dangling bonds formed on the surface F21 of the insulating film 21 are supplied with moisture to be bound with OH groups. This hydrophilizes the surface F21 of the insulating film 21.

Also as for the substrate 12, the steps illustrated in FIGS. 8A to 8C are performed to form dangling bonds on the surface F22 of the insulating film 22 and bind the dangling bonds with OH groups. Accordingly, the surface F22 of the insulating film 22 is also hydrophilized.

Next, as illustrated in FIG. 9A, the insulating film 21 on the substrate 11 and the insulating film 22 on the substrate 12 are placed to face each other, are aligned with each other, and are attached to each other. At that time, a pressurizing mechanism 120 pressurizes substantially the center of the substrate 11 or the substrate 12 in an attachment direction to bring the surface F21 of the insulating film 21 and the surface F22 of the insulating film 22 into direct contact with each other. This hydrogen-bonds the OH groups on the surface F21 of the insulating film 21 and the OH groups on the surface F22 of the insulating film 22 to each other and attaches the substrate 11 and the substrate 12 to each other.

As explained with reference to FIG. 7B, the surface F51 of the end part E51 of the barrier metal 51 is recessed toward the substrate 11 relative to the surface F21 of the insulating film 21 and/or the surface F61 of the electrode part 61. The surface F52 of the end part E52 of the barrier metal 52 is also recessed toward the substrate 12 relative to the surface F22 of the insulating film 22 and/or the surface F62 of the electrode part 62. Therefore, when the substrate 11 and the substrate 12 are attached to each other, a gap is formed between the barrier metal 51 and the barrier metal 52 and the insulating film 21 and the insulating film 22 are bound to each other with no gap formed therebetween. On the other hand, there may be a gap between the electrode part 61 and the electrode part 62. This is because the material of the electrode part 61 or 62 expands and enters into the gap in the thermal treatment process to be described later.

Next, misalignment in relative positions between the substrate 11 and the substrate 12 is detected using a sensor 130 as illustrated in FIG. 9B. When the relative positions of the substrate 11 and the substrate 12 are misaligned by a value equal to or larger than an allowable value, the substrates 11 and 12 are discarded.

Next, infrared light is irradiated from an LED lamp 140 and reflection light is taken by a line camera 150 as illustrated in FIG. 9C. In this way, whether there is a gap (a void) between the insulating film 21 and the insulating film 22 is checked. When a gap larger than an allowable value is found, the substrates 11 and 12 are discarded.

Next, the substrates 11 and 12 attached to each other are thermally treated. For example, the substrates 11 and 12 are annealed for about two hours in an atmosphere at about 300° C. Accordingly, moisture dissociates from the interface between the insulating film 21 and the insulating film 22 and bonds of silicon and oxygen (Si—O bonds) are formed. This causes the insulating film 21 and the insulating film 22 to be bonded more strongly. Furthermore, this thermal treatment process expands the metal materials (copper, for example) of the electrode parts 61 and 62. Accordingly, the electrode part 61 and the electrode part 62 are connected to each other by metallic bonding even if there is a gap between the electrode part 61 and the electrode part 62. Because the barrier metals 51 and 52 are recessed from the surfaces F21 and F22 of the insulating films 21 and 22, respectively, a gap is formed between the barrier metal 51 and the barrier metal 52 even when the substrates 11 and 12 are attached to each other. However, the material of the electrode part 61 or 62 enters into the gap between the barrier metal 51 and the barrier metal 52 due to the thermal treatment. Therefore, the material of the electrode part 61 or 62 is introduced between the barrier metal 51 and the barrier metal 52 as illustrated in FIG. 2. As a result, the gap between the barrier metal 51 and the barrier metal 52 is filled with the material of the electrode part 61 or 62.

Thereafter, the substrates 11 and 12 are further polished or processed. For example, the substrate 12 can be processed using a lithography technique and an etching technique to expose a part of the wire 32 as a bonding pad. Further, the substrates 11 and 12 are singulated into semiconductor chips by dicing.

As described above, according to the present embodiment, formation of a gap between the insulating film 21 and the insulating film 22 at the time of attachment of the first device D1 and the second device D2 can be suppressed by recessing the end part E51 of the barrier metal 51. This suppresses poor attachment between the insulating films 21 and 22. Even if there is a gap of a certain size between the electrode part 61 and the electrode part 62 and between the barrier metal 51 and the barrier metal 52 at an initial time of the attachment, the materials of the electrode parts 61 and 62 expand due to a thermal treatment after the attachment, whereby the electrode part 61 and the electrode part 62 are connected to each other and the material of the electrode 61 or 62 is introduced into the gap between the barrier metal 51 and the barrier metal 52. Therefore, poor connection between the electrode parts 61 and 62 is also suppressed.

Furthermore, the material of the electrode part 61 or 62 can be suppressed from diffusing into the interface (the attachment face) Fa between the insulating film 21 and the insulating film 22 due to receiving of the material of the electrode part 61 or 62 with the gap between the barrier metal 51 and the barrier metal 52. Accordingly, the yield ratio of the first and second devices D1 and D2 can be further improved.

It is preferable that the substrates 11 and 12 are accurately aligned and that the end parts E51 and E52 of the barrier metals 51 and 52 face each other as illustrated in FIG. 2. However, the end parts E51 and E52 of the barrier metals 51 and 52 do not always face each other. For example, FIG. 10 is a sectional view illustrating a manner that the insulating film 21 and the insulating film 22 are misaligned on the attachment face Fa. In FIG. 10, the insulating film 21 and the insulating film 22 are misaligned in a direction parallel to the attachment face Fa. In this case, the surface F51 of the end part E51 of the barrier metal 51 faces the surface F62 of the electrode part 62. The surface F52 of the end part E52 of the barrier metal 52 faces the surface F21 of the insulating film 21. Even if the positions of the barrier metals 51 and 52 are slightly displaced in this way, the material of the electrode part 61 or 62 can enter into the gap between the barrier metals 51 and 52 and thus no problem occurs. Accordingly, even if the positions of the barrier metals 51 and 52 are slightly displaced, effects of the present embodiment can be attained.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first semiconductor substrate;
a first insulating film provided on a first face of the first semiconductor substrate and having a first groove formed thereon;
a first metal layer covering an inner surface of the first groove;
a first electrode part provided on the first metal layer and embedded in the first groove;
a second semiconductor substrate having a second face facing the first face of the first semiconductor substrate;
a second insulating film provided on the second face of the second semiconductor substrate, attached to the first insulating film, and having a second groove formed thereon; and
a second electrode part embedded in the second groove and connected to the first electrode part, wherein
an end part of the first metal layer is recessed toward the first semiconductor substrate relative to a surface of the first insulating film.

2. The device of claim 1, wherein
the end part of the first metal layer is recessed toward the first semiconductor substrate relative to a surface of the first electrode part, and
a material of the first or second electrode part is provided between the end part of the first metal layer and the second insulating film or the second electrode part.

3. The device of claim 1, further comprising a second metal layer provided between the second insulating film and the second electrode part, wherein
an end part of the second metal layer is recessed toward the second semiconductor substrate relative to a surface of the second insulating film.

4. The device of claim 3, wherein
the end part of the second metal layer is recessed toward the second semiconductor substrate relative to a surface of the second electrode part, and
a material of the first or second electrode part is provided between the end part of the second metal layer and the first insulating film, the first electrode part, or the first metal layer.

5. The device of claim 1, further comprising
a second metal layer provided between the second insulating film and the second electrode part, wherein
an end part of the second metal layer is recessed toward the second semiconductor substrate relative to a surface of the second insulating film,
a material of the first or second electrode part is provided between the end part of the first metal layer and the second insulating film or the second electrode part, and
a material of the first or second electrode part is provided between the end part of the second metal layer and the first insulating film, the first electrode part, or the first metal layer.

6. The device of claim 1, wherein
a silicon dioxide film is used as the first and second insulating films,
copper is used as the first and second electrode parts, and
titanium is used as the first metal layer.

7. The device of claim 5, wherein
a silicon dioxide film is used as the first and second insulating films,
copper is used as the first and second electrode parts, and
titanium is used as the first and second metal layers.

8. A manufacturing method of a semiconductor device, the method comprising:
forming a first insulating film on a first face of a first semiconductor substrate;
forming a first groove on the first insulating film;
forming a first metal layer on an inner surface of the first groove;
filling a material of a first electrode part in the first groove;
polishing the first metal layer and the first electrode part until the first insulating film is exposed;
selectively etching the first metal layer to recess an end part of the first metal layer toward the first semiconductor substrate relative to a surface of the first insulating film;
forming a second insulating film on a second face of a second semiconductor substrate;
forming a second groove on the second insulating film;
filling a material of a second electrode part in the second groove;
polishing the second electrode part until the second insulating film is exposed; and
attaching the first semiconductor substrate and the second semiconductor substrate to each other in such a manner that the first insulating film and the second insulating film face each other, thereby connecting the first electrode part and the second electrode part to each other.

9. The method of claim 8, comprising thermally treating the first and second semiconductor substrates after attaching the first and second semiconductor substrates to each other.

10. The method of claim 8, wherein the end part of the first metal layer is recessed toward the first semiconductor substrate relative to a surface of the first electrode part due to etching of the first metal layer.

11. The method of claim 8, wherein the material of the first or second electrode part is introduced between the first metal layer and the second insulating film or the second electrode part due to a thermal treatment of the first and second semiconductor substrates.

12. The method of claim 8, further comprising:
after forming the second groove and before filling the material of the second electrode part,
forming a second metal layer on an inner surface of the second groove;
after filing the material of the second electrode part,
polishing the second metal layer and the second electrode part until the second insulating film is exposed; and
selectively etching the second metal layer to recess an end part of the second metal layer toward the second semiconductor substrate relative to a surface of the second insulating film.

13. The method of claim 12, wherein the end part of the second metal layer is recessed toward the second semiconductor substrate relative to a surface of the second electrode part due to etching of the second metal layer.

14. The method of claim 12, wherein the material of the first or second electrode part is introduced between the second metal layer and the first insulating film, the first electrode part, or the first metal layer due to a thermal treatment of the first and second semiconductor substrates.

15. The method of claim 13, wherein the material of the first or second electrode part is introduced between the second metal layer and the first insulating film, the first electrode part, or the first metal layer due to a thermal treatment of the first and second semiconductor substrates.

16. The method of claim 12, comprising
polishing the first metal layer and the first electrode part until the first insulating film is exposed, the first metal layer protruding relative to the first insulating film and the first electrode part after polishing ends, and
polishing the second metal layer and the second electrode part until the second insulating film is exposed, the second metal layer protruding relative to the second insulating film and the second electrode part after polishing ends.

17. The method of claim 13, comprising
polishing the first metal layer and the first electrode part until the first insulating film is exposed, the first metal layer protruding relative to the first insulating film and the first electrode part after polishing ends, and
polishing the second metal layer and the second electrode part until the second insulating film is exposed, the second metal layer protruding relative to the second insulating film and the second electrode part after polishing ends.

18. The method of claim 16, comprising
filling a material of the first electrode part containing copper in the first groove by electrolytic plating,
filling a material of the second electrode part containing copper in the second groove by electrolytic plating,
selectively etching the first metal layer with a hydrogen peroxide solution, and
selectively etching the second metal layer with a hydrogen peroxide solution.

19. A manufacturing method of a semiconductor device, the method comprising:
forming a first insulating film on a first face of a first semiconductor substrate;
forming a first groove on the first insulating film;
forming a first metal layer on an inner surface of the first groove;
filling a material of a first electrode part containing copper in the first groove by electrolytic plating;
polishing the first metal layer and the first electrode part until the first insulating film is exposed, the first metal layer protruding relative to the first insulating film and the first electrode part after polishing ends;
selectively etching the first metal layer with a hydrogen peroxide solution to recess an end part of the first metal layer toward the first semiconductor substrate relative to a surface of the first insulating film;
forming a second insulating film on a second face of a second semiconductor substrate;
forming a second groove on the second insulating film;
forming a second metal layer on an inner surface of the second groove;
filling a material of a second electrode part containing copper in the second groove by electrolytic plating;
polishing the second metal layer and the second electrode part until the second insulating film is exposed, the second metal layer protruding relative to the second insulating film and the second electrode part after polishing ends;
selectively etching the second metal layer with a hydrogen peroxide solution to recess an end part of the second metal layer toward the second semiconductor substrate relative to a surface of the second insulating film;
attaching the first semiconductor substrate and the second semiconductor substrate to each other in such a manner that the first insulating film and the second insulating film face each other;
thermally treating the first and second semiconductor substrates; and
connecting the first electrode part and the second electrode part to each other.

20. The method of claim 19, wherein
due to a thermal treatment of the first and second semiconductor substrates,
a material of the first or second electrode part is introduced between the first metal layer and the second insulating film or the second electrode part, and
a material of the first or second electrode part is introduced between the second metal layer and the first insulating film, the first electrode part, or the first metal layer.
